(19) United States
(12) Patent Application Publication
(10) Pub. No.: US 2018/0188093 A1
(43) Pub. Date: Jul. 5, 2018

(54) WATER FLOW METER

(71) Applicant: Maxwell Danlogo, West Valley City, UT (US)

(72) Inventor: Maxwell Danlogo, West Valley City, UT (US)

(21) Appl. No.: 15/398,994

(22) Filed: Jan. 5, 2017

(51) Int. Cl. G01F 15/06; G06K 7/14

(52) U.S. Cl. CPC G01F 15/068; G01R 31/3682; G06K 7/1413

(57) ABSTRACT

A water flow meter that includes: a flow tube, wherein the flow tube is adapted to connect in line with a water pipe; a water flow sensor wherein the water flow sensor measures water flow through the flow tube; and a threaded connector at each end of the flow tube in order to connect the flow tube into the water line of a user. The water flow meter further includes a battery and a battery indicator with a generator. Other aspects of the water flow meter include memory in the form of a SD card slot and Wi-Fi connectivity.

### BACKGROUND OF THE INVENTION

### Field of Invention

The present invention relates to a commercial or residential water flow meter.

### Description of Related Art

Individuals especially homeowners must typically incur water bills and therefore monitor water usage. Although some devices have been developed for this purpose many are not effective enough to provide a complete record in a timely manner to the consumer. It can be imperative for consumers to maintain a real-time measure of water usage in order to control costs. Further in some areas of the country water usage is at a premium and therefore it is imperative for water conservation that users to maintain accurate data related to water usage. As a result, an effective water flow meter providing real time data may be an asset to the existing art.

### SUMMARY OF THE INVENTION

The present invention relates to a water flow meter that includes: a flow tube, wherein the flow tube is adapted to connect in line with a water pipe; a water flow sensor wherein the water flow sensor measures water flow through the flow tube; and a threaded connector at each end of the flow tube in order to connect the flow tube into the water line of a user. The water flow meter further includes a battery and a battery indicator with a generator. Other aspects of the water flow meter include memory in the form of a SD card slot and Wi-Fi connectivity.

### BRIEF DESCRIPTION OF DRAWINGS

FIG. 1 depicts a water flow meter in accordance with the present invention.

FIG. 2 depicts cross-sectional views of the water flow meter in accordance with the present invention.

FIG. 3 depicts a front view of the water flow meter in accordance with the present invention.

FIG. 4 depicts a diagram showing steps related to the use the water flow meter in accordance with the present invention.

### DETAILED DESCRIPTION

The present invention relates to a water flow meter that connects in line with a water pipe. The water flow meter includes a sensor that detects water flow and provides a measurement in a desired unit. As the water flows through the water meter this data is collected and stored on memory within the water meter. Further aspects of the water flow meter include a battery that supplies power for the components of the water meter. Further Wi-Fi connectivity is provided on the water meter to transmit data to a computer or hand held device wirelessly connected to the water meter. Other features of the water flow meter include a battery and a generator that charges the battery as needed. A battery indicator is also shown indicating the status of the battery during use. The water flow meter may also include a screen that provides an image of data related to water flow. The present invention further includes a barcode on each water meter so that multiple water meters may be used at one location. A user will be able to track total water usage at multiple water usage locations, i.e., kitchen, first bathroom, second bathroom. Each water meter includes a unique barcode that is scanned using a smartphone.

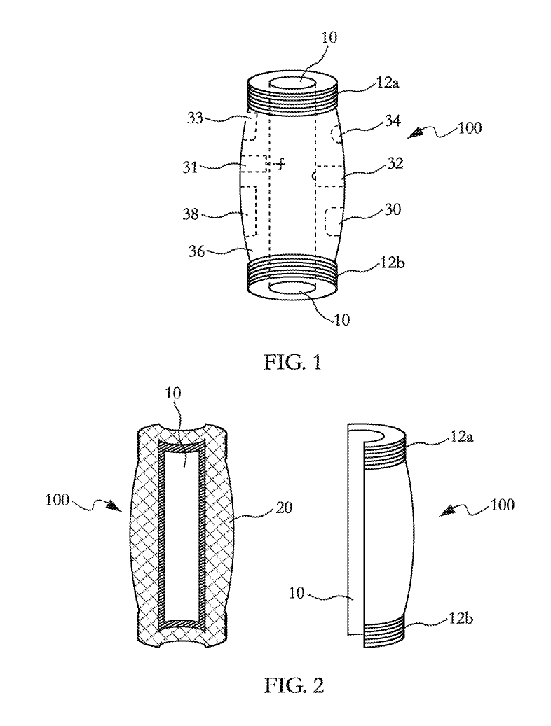

In reference to FIG. 1, a water flow meter 100 in accordance with the present invention is depicted. The water flow meter 100 includes a flow tube 10 with connecting threads at each end of the flow tube 10. Connecting threads 12a, 12b are shown in FIG. 1. The flow tube 10 allows for the flow of water through the flow meter. Threads 12a, 12b allow for the connection of the flow meter 100 in line with the water supply of a residence. FIG. 2 provides cross-sectional view of the flow meter 100 in accordance with the present invention, where the interior of flow tube 10 is shown.

Other components of the flow meter 100 include water sensor 32 and battery 38 with battery indicator 36. The battery 38 supplies power to the sensor and other components of the flow meter 100. A small generator 31 is also shown. The generator 31 provides a means to power the battery 38 and is operated via the flow of water through flow tube 10. Further the flow meter 100 includes memory in the form of a SD card slot 33. This memory allows the meter to store data related to water flow through the flow tube 10. Further a converter 34 is also shown in FIG. 1 above the water sensor 32. One additional aspect of the flow meter 100 is the ability to transfer data wirelessly through a Wi-Fi connection provided by transmitter 30. Transmitter 30 transmits data to a computer, tablet or smartphone of the user in order to provide handy accurate data related to water flow through the flow tube 10.

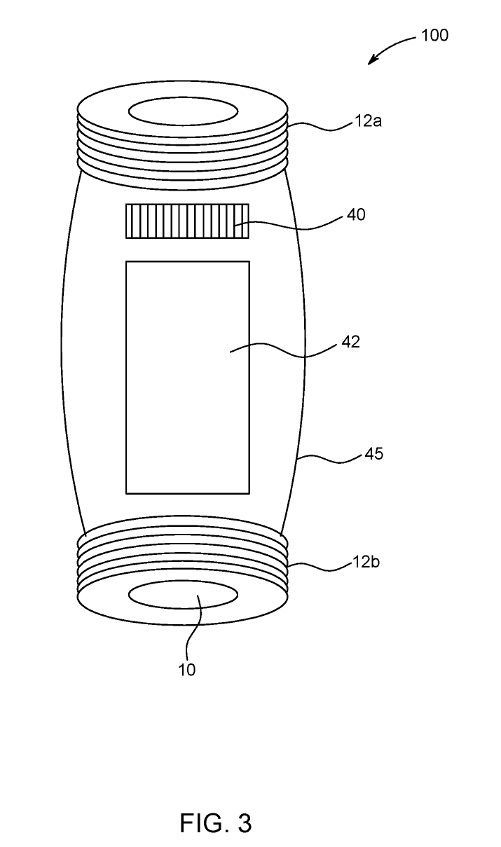

FIG. 3 shows a front view of the flow meter 100. Each flow meter 100 includes a barcode 40 and an interactive touch screen 42. The barcode 40 provides a unique identifier for each flow meter 100. Preferably multiple flow meters 100 are placed in a system and the barcode 40 helps to identify the location, thus the flow meters 100 may determine overall water usage and usage associated with designated locations as desired. The interactive touch screen 42 enables a user to gather data from the flow meter concerning water usage. Further the flow meter 100 is encased within a brass casing 45.

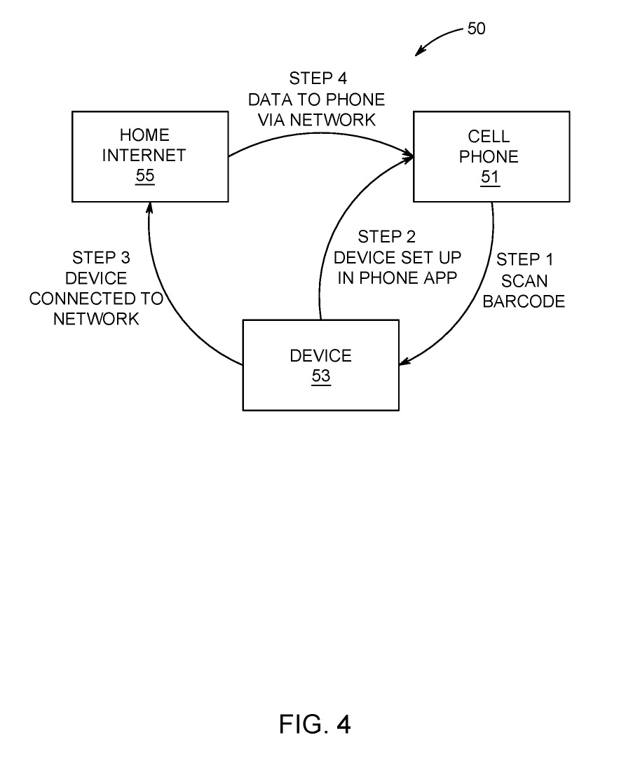

FIG. 4 provides a flow diagram depicting steps related to the usage of the flow meter 100. Initially a user scans a barcode using a smartphone 51 and the water meter (device) 53 is set up through an application stored on the smartphone 51. Data related to device 53 is sent to the smartphone 51 via a network 55, where data may then be viewed and analyzed. As a consequence, a user is provided with periodic updates on water usage using a plurality of devices 53 installed in a residence or building.

The foregoing descriptions of specific embodiments of the present invention have been presented for purposes of illustration and description. They are not intended to be exhaustive or to limit the invention to the precise forms disclosed, and obviously many modifications and variations are possible in light of the above teaching. The exemplary embodiment was chosen and described in order to best explain the principles of the invention and its practical application, to thereby enable others skilled in the art to best utilize the invention and various embodiments with various modifications as are suited to the particular use contemplated.

What is claimed is:

1. A water flow meter comprising:
a flow tube, wherein the flow tube is adapted to connect in line with a water pipe;
a water flow sensor wherein the water flow sensor measures water flow through the flow tube; and
a threaded connector at each end of the flow tube in order to connect the flow tube into the water line of a user.

2. The water flow meter according to claim 1 further including a battery and a battery indicator.

3. The water flow meter according to claim 1 further including a generator.

4. The water flow meter according to claim 1 further including memory in the form of a SD card slot.

5. The water flow meter according to claim 1 further including Wi-Fi connectivity.

6. The water flow meter according to claim 1, further including a barcode identifier.

7. The water flow meter according to claim 1, further including an interactive screen.
